(19) United States
(12) Patent Application Publication
(10) Pub. No.: US 2025/0099904 A1
(43) Pub. Date: Mar. 27, 2025

(54) OZONE CONCENTRATOR, SUBSTRATE PROCESSING APPARATUS, AND OZONE SUPPLY METHOD

(71) Applicant: Tokyo Electron Limited, Tokyo (JP)

(72) Inventor: Yuki CHIDA, Oshu City (JP)

(21) Appl. No.: 18/830,662

(22) Filed: Sep. 11, 2024

(30) Foreign Application Priority Data
Sep. 22, 2023 (JP) 2023-159094

(51) Int. Cl. B01D 53/047; C01B 13/10

(52) U.S. Cl. CPC B01D 53/0476; C01B 13/10; B01D 2256/14; B01D 2259/40009; B01D 2259/402; C01B 2210/0014

(57) ABSTRACT

An ozone concentrator includes: a pump provided in a supply passage through which an ozone gas flows; a flow rate controller provided in the supply passage downstream of the pump; and a pressure controller configured to control a pressure of the supply passage between the pump and the flow rate controller to a set pressure.

### CROSS-REFERENCE TO RELATED APPLICATION

This application is based upon and claims the benefit of priority from Japanese Patent Application No. 2023-159094, filed on Sep. 22, 2023, the entire contents of which are incorporated herein by reference.

### TECHNICAL FIELD

The present disclosure relates to an ozone concentrator, a substrate processing apparatus, and an ozone supply method.

### BACKGROUND

An ozone gas concentrating apparatus is known that adsorbs an ozone gas generated by an ozone generator onto an adsorbent and vacuum-desorbs the ozone gas by a function of a vacuum pump attached to a gas outlet path during desorption (see, for example, Patent Document 1).

### PRIOR ART DOCUMENT

### Patent Document

Patent Document 1: Japanese Patent No. 5427412

### SUMMARY

According to one embodiment of the present disclosure, there is provided an ozone concentrator, including: a pump provided in a supply passage through which an ozone gas flows; a flow rate controller provided in the supply passage downstream of the pump; and a pressure controller configured to control a pressure of the supply passage between the pump and the flow rate controller to a set pressure.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a diagram showing a substrate processing apparatus according to an embodiment.

FIG. 2 is a diagram showing a result of the embodiment.

FIG. 3 is a diagram showing a result of a comparative example.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, non-limiting embodiments of the present disclosure are described with reference to the accompanying drawings. In all the accompanying drawings, the same or corresponding members or components are denoted by the same or corresponding reference numerals, and redundant explanations thereof are omitted.

### <Substrate Processing Apparatus>

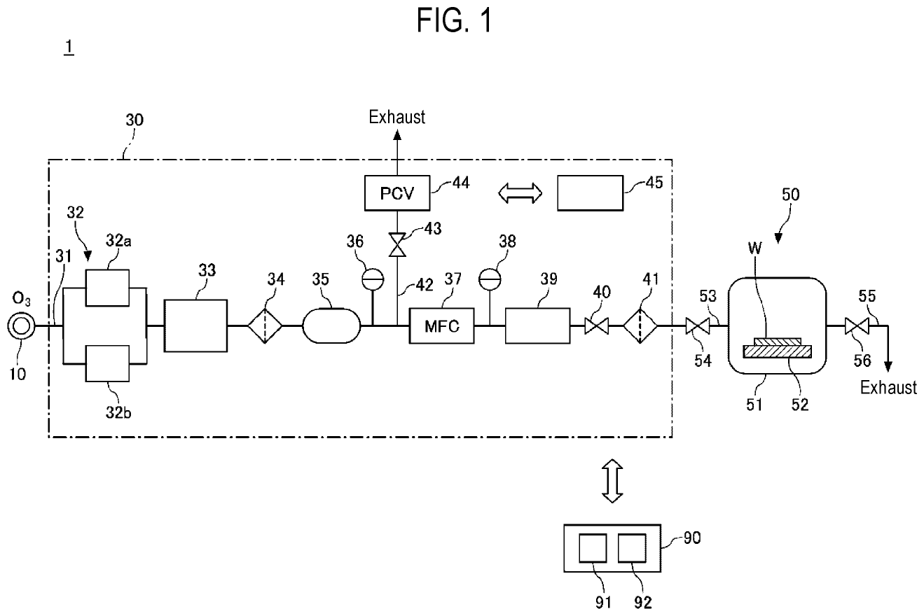

A substrate processing apparatus 1 according to an embodiment is described with reference to FIG. 1. FIG. 1 is a diagram showing the substrate processing apparatus 1 according to the embodiment.

The substrate processing apparatus 1 includes an ozone generator 10, an ozone concentrator 30, a processor 50, and an apparatus controller 90.

The ozone generator 10 generates an ozone gas.

The ozone concentrator 30 includes a supply passage 31, an adsorber 32, a pump 33, a first filter 34, a buffer tank 35, a first pressure gauge 36, a flow rate controller 37, a second pressure gauge 38, a concentration meter 39, an on-off valve 40, a second filter 41, a vacuum exhaust passage 42, an on-off valve 43, a pressure controller 44, and a controller 45.

The supply passage 31 connects the ozone generator 10 and the processor 50. The supply passage 31 allows the ozone gas generated by the ozone generator 10 to flow therethrough and supplies the ozone gas to the processor 50. The supply passage 31 is provided with the adsorber 32, the pump 33, the first filter 34, the buffer tank 35, the first pressure gauge 36, the flow rate controller 37, the second pressure gauge 38, the concentration meter 39, the on-off valve 40, and the second filter 41 in this order from an upstream.

The adsorber 32 includes two adsorption columns 32a and 32b. The two adsorption columns 32a and 32b are connected in parallel to each other. In this case, while desorption operation is performed in one adsorption column 32a (or the adsorption column 32b), adsorption operation is performed in the other adsorption column 32b (or the adsorption column 32a), thereby continuously supplying the ozone gas to a downstream of the supply passage 31. The adsorber 32 may include only one adsorption column or may include three or more adsorption columns. Each of the adsorption columns 32a and 32b is filled with an adsorbent that selectively adsorbs the ozone gas. The adsorbent is, for example, silica gel. The adsorbent may also be zeolite.

The pump 33 sends the ozone gas to the downstream of the supply passage 31. The pump 33 depressurizes and exhausts the ozone gas collected in the adsorption columns 32a and 32b and supplies the ozone gas thereof to the downstream.

The first filter 34 filters the ozone gas flowing through the supply passage 31 and removes foreign substances contained in the ozone gas.

The buffer tank 35 temporarily stores the ozone gas. The buffer tank 35 averages a concentration of the ozone gas when there is a change in the concentration of the ozone gas from the adsorption columns 32a and 32b. This allows the ozone gas to be supplied to the downstream of the supply passage 31 while maintaining the ozone gas at a concentration within a certain range.

The first pressure gauge 36 is provided in the supply passage 31 between the buffer tank 35 and the flow rate controller 37. The first pressure gauge 36 detects a pressure of the ozone gas flowing through the supply passage 31 between the buffer tank 35 and the flow rate controller 37. The first pressure gauge 36 detects a primary pressure of the flow rate controller 37.

The flow rate controller 37 controls a flow rate of the ozone gas flowing through the supply passage 31. The flow rate controller 37 is, for example, a mass flow controller (MFC).

The second pressure gauge 38 is provided in the supply passage 31 between the flow rate controller 37 and the concentration meter 39. The second pressure gauge 38 detects a pressure of the ozone gas flowing through the supply passage 31 between the flow rate controller 37 and the concentration meter 39. The second pressure gauge 38 detects a secondary pressure of the flow rate controller 37.

The concentration meter 39 detects the concentration of the ozone gas flowing through the supply passage 31.

The on-off valve 40 is a valve that switches on and off a flow of the ozone gas. When the on-off valve 40 is in an open state, the ozone gas flows into the second filter 41 located downstream, and when the on-off valve 40 is in a closed state, the ozone gas does not flow into the second filter 41 located downstream.

The second filter 41 filters the ozone gas flowing through the supply passage 31 and removes foreign substances contained in the ozone gas.

The vacuum exhaust passage 42 branches off from the supply passage 31 between the buffer tank 35 and the flow rate controller 37. The vacuum exhaust passage 42 exhausts the ozone gas inside the supply passage 31. The vacuum exhaust passage 42 is provided with the on-off valve 43 and the pressure controller 44 in this order from an upstream.

The on-off valve 43 is a valve that switches on and off the flow of the ozone gas. When the on-off valve 43 is in an open state, the ozone gas flows into the pressure controller 44 located downstream, and when the on-off valve 43 is in a closed state, the ozone gas does not flow into the pressure controller 44 located downstream.

The pressure controller 44 incorporates a pressure gauge that detects a primary pressure of the pressure controller 44. The pressure controller 44 controls the pressure detected by the incorporated pressure gauge to a set pressure. Therefore, a pressure of the vacuum exhaust passage 42 at an upstream of the pressure controller 44 is adjusted to the set pressure. When the on-off valve 43 is in the open state, the vacuum exhaust passage 42 at the upstream of the pressure controller 44 is in fluid communication with the supply passage 31 between the buffer tank 35 and the flow rate controller 37. Therefore, when the on-off valve 43 is in the open state, the pressure of the supply passage 31 between the buffer tank 35 and the flow rate controller 37 is adjusted to the set pressure. As a result, the primary pressure of the flow rate controller 37 is stabilized, and thus it is possible to execute stabilized flow rate control when supplying the ozone gas to the processor 50. The pressure controller 44 is, for example, a pressure control valve (PCV).

The pressure controller 44 may control the pressure detected by the first pressure gauge 36 to the set pressure. Even in this case, the pressure of the supply passage 31 between the buffer tank 35 and the flow rate controller 37 is adjusted to the set pressure in the same manner as above. As a result, the primary pressure of the flow rate controller 37 is stabilized, and thus it is possible to execute stabilized flow rate control when supplying the ozone gas to the processor 50.

The set pressure is, for example, a fixed value determined in advance. The fixed value may be equal to or greater than, for example, a sum of a minimum required differential pressure of the flow rate controller 37 and the secondary pressure of the flow rate controller 37 that may be obtained when a set flow rate of the flow rate controller 37 is changed from a minimum controllable flow rate to a maximum controllable flow rate. In this case, even if the set flow rate of the flow rate controller 37 is changed to any flow rate from the minimum controllable flow rate to the maximum controllable flow rate, it is possible to perform stabilized flow rate control when supplying the ozone gas to the processor 50. The secondary pressure of the flow rate controller 37 may be detected by the second pressure gauge 38.

The set pressure may be a variable value determined according to the pressure detected by the second pressure gauge 38. The set pressure may be a sum of the pressure detected by the second pressure gauge 38 and the minimum required differential pressure of the flow rate controller 37. In this case, a secondary pressure of the pump 33 may be reduced. Therefore, a durability of the pump 33 is improved.

The controller 45 may control the set pressure of the pressure controller 44 to be the sum of the pressure detected by the second pressure gauge 38 and the minimum required differential pressure of the flow rate controller 37. When the set flow rate of the flow rate controller 37 is large, the pressure detected by the second pressure gauge 38 becomes high, and when the set flow rate of the flow rate controller 37 is small, the pressure detected by the second pressure gauge 38 becomes low. In this way, the pressure detected by the second pressure gauge 38 varies depending on the set flow rate of the flow rate controller 37. Therefore, since the controller 45 controls the set pressure of the pressure controller 44 to be the sum of the pressure detected by the second pressure gauge 38 and the minimum required differential pressure of the flow rate controller 37, it is possible to reduce the secondary pressure of the pump 33 regardless of the set flow rate of the flow rate controller 37.

The processor 50 includes a processing container 51, a holder 52, an introduction passage 53, an on-off valve 54, an exhaust passage 55, and an on-off valve 56.

The processing container 51 is a container in which a processing space capable of accommodating a substrate W is formed therein. In the processing space, the substrate W is processed. The substrate W is, for example, a semiconductor wafer.

The holder 52 is provided inside the processing container 51. The holder 52 holds, for example, one sheet of substrate W horizontally. The holder 52 may also hold two or more sheets of substrates W horizontally.

The introduction passage 53 connects the supply passage 31 and the processing container 51. The introduction passage 53 introduces the ozone gas from the supply passage 31 into the processing container 51. The introduction passage 53 is provided with the on-off valve 54.

The on-off valve 54 is a valve that switches on and off the flow of the ozone gas. When the on-off valve 54 is in an open state, the ozone gas flows into the processing container 51 located downstream, and when the on-off valve 54 is in a closed state, the ozone gas does not flow into the processing container 51 located downstream.

The exhaust passage 55 is connected to the processing container 51. The exhaust passage 55 exhausts the ozone gas inside the processing container 51. The exhaust passage 55 is provided with the on-off valve 56.

The on-off valve 56 is a valve that switches on and off the flow of the ozone gas. When the on-off valve 56 is in an open state, the ozone gas flows into the exhaust passage 55 located downstream, and when the on-off valve 56 is in a closed state, the ozone gas does not flow into the exhaust passage 55 located downstream.

The apparatus controller 90 is, for example, a computer, and includes an operator 91 and a storage 92. The storage 92 stores programs that control various processes executed in the substrate processing apparatus 1. The operator 91 controls the operation of the substrate processing apparatus 1 by reading and executing the programs stored in the storage 92. The programs may be recorded in a computer-readable storage medium and installed in the storage 92 of the apparatus controller 90 from the storage medium. The computer-readable storage medium includes, for example, a hard disk (HD), a flexible disk (FD), a compact disc (CD), a magneto-optical (MO) disk, and a memory card, etc. Instead of the controller 45, the apparatus controller 90 may control the set pressure of the pressure controller 44 to be the sum of the pressure detected by the second pressure gauge 38 and the minimum required differential pressure of the flow rate controller 37.

### <Ozone Supply Method>

An example of a method in which the ozone concentrator 30 supplies the ozone gas to the processor 50 will now be described. When the ozone concentrator 30 supplies the ozone gas to the processor 50, the controller 45 controls the on-off valve 43 to be in an open state, and the pressure controller 44 controls the pressure detected by the incorporated pressure gauge or the pressure detected by the first pressure gauge 36 to the set pressure. In this case, the pressure of the supply passage 31 between the buffer tank 35 and the flow rate controller 37 is adjusted to the set pressure. Therefore, the primary pressure of the flow rate controller 37 is stabilized, and thus it is possible to perform stabilized flow control when supplying the ozone gas to the processor 50.

When the ozone concentrator 30 supplies the ozone gas to the processor 50, it is also possible that the controller 45 controls the set pressure of the pressure controller 44 to be the sum of the pressure detected by the second pressure gauge 38 and the minimum required differential pressure of the flow rate controller 37. In this case, it is possible to reduce the secondary pressure of the pump 33. Therefore, the durability of the pump 33 is improved.

### <Evaluation Results>

In the substrate processing apparatus 1 according to the embodiment, a change in the primary pressure of the flow rate controller 37 and a change in the flow rate of the ozone gas were measured when the ozone gas was supplied to the processor 50 while changing the set flow rate of the flow rate controller 37 (embodiment). In the embodiment, the pressure controller 44 supplied the ozone gas to the processor 50 while controlling the pressure detected by the first pressure gauge 36 to the set pressure. In this case, the controller 45 controlled the set pressure to be the sum of the pressure detected by the second pressure gauge 38 and the minimum required differential pressure of the flow rate controller 37.

For comparison, in a substrate processing apparatus (not shown) excluding the pressure controller 44 from the substrate processing apparatus 1, a change in the primary pressure of the flow rate controller 37 and a change in the flow rate of the ozone gas were measured when the ozone gas was supplied to the processor 50 while changing the set flow rate of the flow rate controller 37 (comparative example). In the comparative example, when the pressure detected by the first pressure gauge 36 exceeded a threshold pressure, the on-off valve 43 was changed from a closed state to an open state, so that the ozone gas was supplied to the processor 50 while controlling the primary pressure of the flow rate controller 37 to be equal to or lower than the threshold pressure.

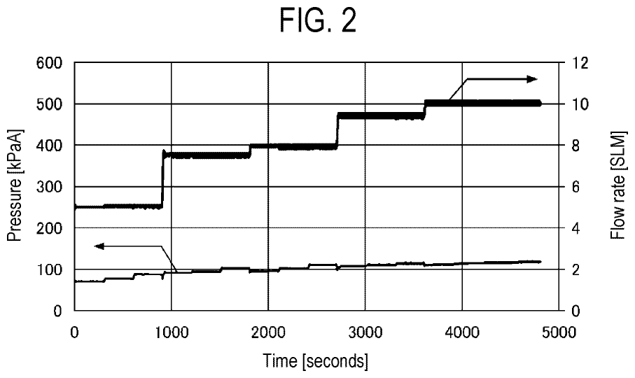

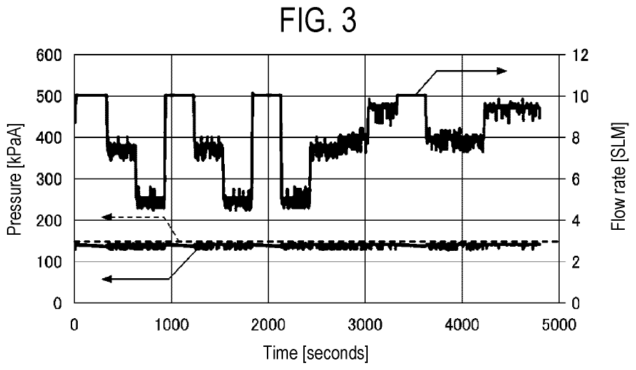

FIG. 2 is a diagram showing a result of the embodiment. FIG. 3 is a diagram showing a result of the comparative example. In FIGS. 2 and 3, a horizontal axis denotes time (seconds), a vertical axis on the left denotes pressure (primary pressure of the flow rate controller 37) (kPaA) detected by the first pressure gauge 36, and a vertical axis on the right denotes a flow rate (SLM) detected by the flow rate controller 37. In FIG. 3, the threshold pressure is denoted by a broken line.

As shown in FIG. 2, it is seen in the embodiment that, even when the set flow rate of the flow rate controller 37 is changed, stabilized flow control is performed without flow rate fluctuation. This is considered to be a result of the primary pressure of the flow rate controller 37 being stabilized by the pressure control in the pressure controller 44. In contrast, as shown in FIG. 3, it is seen in the comparative example that flow rate fluctuation after the set flow rate of the flow rate controller 37 is changed is large. This is considered to be because pressure fluctuation is large when the on-off valve 43 is opened and closed, and the primary pressure of the flow rate controller 37 fluctuates according to the opening and closing of the on-off valve 43.

In addition, as shown in FIG. 2, it is seen in the embodiment that, when the set flow rate of the flow rate controller 37 is changed in a range of 5 SLM to 10 SLM, the primary pressure of the flow rate controller 37 is 80 kPaA to 120 kPaA. In contrast, as shown in FIG. 3, it is seen in the comparative example that, when the set flow rate of the flow rate controller 37 is changed in the range of 5 SLM to 10 SLM, the primary pressure of the flow rate controller 37 is 130 kPaA to 150 kPaA. From these results, it is shown that the primary pressure of the flow rate controller 37, i.e., the secondary pressure of the pump 33, is possible to be lowered in the embodiment compared to the comparative example.

According to the present disclosure in some embodiments, it is possible to execute stabilized flow rate control when supplying an ozone gas.

While certain embodiments have been described, these embodiments have been presented by way of example only, and are not intended to limit the scope of the disclosure. Indeed, the embodiments described herein may be embodied in a variety of other forms. Furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. An ozone concentrator, comprising:
a pump provided in a supply passage through which an ozone gas flows;
a flow rate controller provided in the supply passage downstream of the pump; and
a pressure controller configured to control a pressure of the supply passage between the pump and the flow rate controller to a set pressure.

2. The ozone concentrator of claim 1, wherein the pressure controller is provided in a vacuum exhaust passage branched off from the supply passage between the pump and the flow rate controller.

3. The ozone concentrator of claim 2, wherein the set pressure is a predetermined fixed value.

4. The ozone concentrator of claim 2, further comprising a pressure gauge configured to detect a pressure of the supply passage downstream of the flow rate controller,
wherein the set pressure is a variable value determined based on the pressure detected by the pressure gauge.

5. The ozone concentrator of claim 4, further comprising a controller configured to control the set pressure to be a sum of the pressure detected by the pressure gauge and a minimum required differential pressure of the flow rate controller.

6. The ozone concentrator of claim 1, wherein the set pressure is a predetermined fixed value.

7. The ozone concentrator of claim 1, further comprising a pressure gauge configured to detect a pressure of the supply passage downstream of the flow rate controller,
wherein the set pressure is a variable value determined based on the pressure detected by the pressure gauge.

8. The ozone concentrator of claim 7, further comprising a controller configured to control the set pressure to be a sum of the pressure detected by the pressure gauge and a minimum required differential pressure of the flow rate controller.

9. A substrate processing apparatus, comprising:
a processor configured to process a substrate; and
an ozone concentrator connected to the processor,
wherein the ozone concentrator includes:
a pump provided in a supply passage through which an ozone gas flows;
a flow rate controller provided in the supply passage downstream of the pump; and
a pressure controller configured to control a pressure of the supply passage between the pump and the flow rate controller to a set pressure.

10. An ozone supply method of supplying an ozone gas by an ozone concentrator,
wherein the ozone concentrator includes:
a pump provided in a supply passage through which the ozone gas flows;
a flow rate controller provided in the supply passage downstream of the pump;
a pressure controller configured to control a pressure of the supply passage between the pump and the flow rate controller to a set pressure; and
a pressure gauge configured to detect a pressure of the supply passage downstream of the flow rate controller, and
wherein the ozone supply method comprises controlling the set pressure to be a sum of the pressure detected by the pressure gauge and a minimum required differential pressure of the flow rate controller.
